(19) United States
(12) Patent Application Publication
(10) Pub. No.: US 2002/0123228 A1
(43) Pub. Date: Sep. 5, 2002

(54) Method to improve the reliability of gold to aluminum wire bonds with small pad openings

(76) Inventors: Richard C. Smoak, Austin, TX (US); James E. Morris JR., Austin, TX (US); Margaret C. Tait, Red Rock, TX (US); Kevin O'Dwyer, Austin, TX (US)

Correspondence Address: FLIESLER DUBB MEYER & LOVEJOY, LLP, FOUR EMBARCADERO CENTER, SUITE 400, SAN FRANCISCO, CA, 94111, US

(21) Appl. No.: 09/798,509

(22) Filed: Mar. 2, 2001

(51) Int. Cl. H01L 21/4763; H01L 23/50; H01L 21/50

(52) U.S. Cl. 438/706; 438/624; 257/635

(57) ABSTRACT

In method for manufacturing an integrated circuit improves the reliability of thermosonic bonds formed to attach a gold bond wire to an aluminum interconnect pad, where a pad opening in the integrated circuit is on the order of 60 microns. In the method, a reactive ion etch (RIE) passivation etch is used which does not include a, more corrosive sulfur hexa-fluoride to remove the SiO₂ passivation layer above the pad. Instead, the RIE uses argon as the carrier gas, carbon tetrafluoride (CF₄) and trifluoromethane (CHF₃) as active etchants, and oxygen (O₂) to reduce the residual halide contaminant in the aluminum pad. Further, a thin titanium layer is deposited beneath the aluminum pad layer to improve adhesion of the aluminum pad to underlying layers of the semiconductor integrated circuit. The aluminum pad layer is made very thin, or less than approximately 8000 Å, to limit Kirkendall voiding.

### BACKGROUND OF THE INVENTION

1. Field of the Invention

The present invention relates generally to the manufacturing process of semiconductor devices, and more particularly to etching of a passivation layer over a metal pad interconnect surface, and construction of the pad to improve adhesion when a gold wire is bonded to the pad using a thermosonic bond.

2. Background

Microelectronic circuit manufacturers typically manufacture integrated circuits with interconnect pad regions exposed in openings of a top passivation layer. The top passivation layer is formed from silicon dioxide (SiO₂) which serves to protect underlying circuitry. The metal pad provides a region for interconnection of components in the integrated circuit to external components. A bonding wire is soldered or otherwise attached to the pad to enable connection to the external circuitry. Vias connect the pad internally to a lower metalization region which forms an interconnect line to connect to components in the integrated circuit.

During the manufacturing process to expose the pad regions, a photoresist mask is applied to the top passivation layer which initially covers the entire integrated circuit. Openings in the photoresist mask are provided over the pad regions. A passivation etch is then applied to the integrated circuit to etch away the passivation layer over the pads where it is exposed by openings in the photoresist mask.

The passivation etch typically contains sulfur hexafluoride (SF₆). The SF₆ etchant is sometimes undesirable, however, because of the corrosive nature of sulfur combined with moisture when the integrated circuit is included in plastic assembled parts.

When an integrated circuit contains heat sensitive components, a thermosonic ball-bonding process is used to attach an interconnect wire or ribbon to the metal pad. Thermosonic bonding uses a combination of a relatively low temperature, pressure, and a high frequency to bond the ribbon or wire conductor to the metal interconnect pad which provides connectivity to the sensitive circuitry. Relatively low temperature indicates a temperature no greater than the temperature that would potentially cause a modification of the circuit parameters of at least one of the system components. Such a minimum temperature may range up to 150 degrees Celsius, significantly lower than typical soldering temperatures. A substrate is typically heated by the way of a heating plate upon which the integrated substrate is clamped, and pressure is further applied to the substrate.

The temperature is applied while the ultrasonic bonding frequency ranging from 60 KHz up to 140 KHz is applied to the wire bonding lead. The combination of the application of high temperature, pressure, and the moderate ultrasonic frequency abrasion operates to effect metallurgical atomic diffusion bonding of the wire bond with the metal pad bonding site. The high frequency range achieves the requisite atomic diffusion bonding energy, without causing fracturing or destruction of the bonding wire or its interface with the metal bond pad.

It is desirable to provide a pad structure which maximizes the mechanical adhesion of the aluminum pad region, along with the adhesion of the aluminum pad to conductive components inside the integrated circuit when a thermosonic bonding process is used.

### SUMMARY OF THE INVENTION

In accordance with the present invention a method is provided to improve the reliability of gold to aluminum thermosonic bonds by removing or reducing corrosive contaminants from a passivation etch, and improving the mechanical adhesion of the aluminum bonding pad to underlying connection circuitry.

In the method in accordance with the present invention a reactive ion etch (RIE) passivation etch is used which does not include sulfur hexa-fluoride. Instead, the RIE uses argon as the carrier gas, carbon tetrafluoride (CF₄) and trifluoromethane (CHF₃) as active etchants, and oxygen (O₂) to reduce the residual halide contaminant in an aluminum pad.

Further in one embodiment of the present invention, a thin titanium layer is deposited beneath the aluminum pad layer to improve adhesion of the aluminum pad to underlying layers of the semiconductor integrated circuit.

In a further embodiment, the aluminum pad layer is made very thin, or less than approximately 8000 Å, to limit Kirkendall voiding caused by gold (Au) atoms from gold wire bonds diffusing into the aluminum pad layer.

### BRIEF DESCRIPTION OF THE DRAWINGS

The present invention will be described with respect to particular embodiments thereof, and references will be made to the drawings in which:

FIG. 1 shows a cross-section of a semiconductor device in accordance with the present invention with a thermosonic ball bonded wire bond;

FIG. 2 shows an alternative cross-section of a semiconductor device in accordance with the present invention;

FIG. 3 shows a cross-section of the semiconductor device of FIG. 1 during manufacture before passivation etching; and

FIG. 4 illustrates the semiconductor device-of FIG. 3 following a passivation etch step.

### DETAILED DESCRIPTION

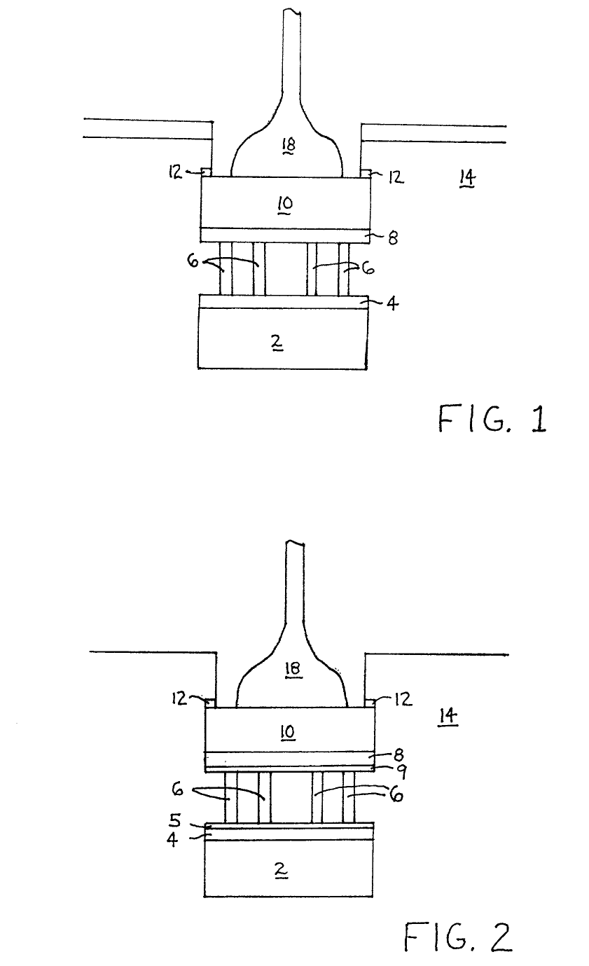

FIG. 1 shows the cross-section of a semiconductor device in accordance with the present invention with an interconnect pad 10 and wire bond 18. The pad 10 is formed using a deposited aluminum region. A wire 18, which is preferably gold, is bonded to the aluminum pad 10 using a thermosonic bonding process. The pad 10 is connected by tungsten filled vias 6 to an aluminum interconnect line 2 to provide signal connections to semiconductor components (not shown) formed in the semiconductor substrate.

To fabricate the integrated circuit, an aluminum metalization region is deposited on a silicon substrate and etched to form an interconnect line region 2 which connects to integrated circuit components (not shown) in the substrate. The interconnect line 2 may be several material layers above the base of the integrated circuit substrate, with underlying layers used to form the internal integrated circuit components which are not shown.

A thin layer of titanium nitride (TiN) 4 is deposited using a titanium arc ion plating process onto the aluminum line region 2. With the interconnect line region 2 being aluminum, the TiN coating 4 is used to avoid the formation of an insulating film resulting from reactions between fluorine and aluminum, the presence of fluorine being due to the fact that tungsten depositions (vias 6 discussed subsequently) are formed with tungsten fluorides.

FIG. 2 shows an alternative layout to the layout of FIG. 1. In FIG. 2, a thin titanium layer 5 is deposited over the TiN nitride layer 4. The thin titanium layer enhances the wettability along via walls 6 in which the tungsten is later deposited, essentially forming a glue layer or adhesion enhancer. Note, components carried over from FIG. 1 to FIG. 2 are similarly labeled, as will be components carried over in subsequent drawings.

A portion of the passivation layer 14 made of SiO₂ is then typically grown over the TiN layer 4, or Ti/TiN 4/5 layer up to the bottom of a metalization layer 8, the metalization layer 8 being discussed subsequently. This portion of the SiO₂ insulates one or more metalization or other layers (not shown) which provide connections to components in the integrated circuit above the metalization layer 2. Vias 6 are then formed in this portion of the passivation layer 14 by first applying a photoresist mask with openings where the vias 6 are to be formed, and then applying a passivation etch to remove the passivation layer 14 where the photoresist mask does not cover. The vias 6 are then filled with tungsten to provide an electrical connection to the aluminum interconnect line 2. A number of vias 6 are used to decrease electrical resistance and reduce parasitic capacitance.

A thin titanium layer 8 is next deposited to cover the tungsten filled vias 6. In one embodiment, the titanium layer thickness ranges from 150-250 Å. The thin titanium layer 8 improves the mechanical adhesion of the aluminum film 10 applied above the titanium layer 8 in a subsequent step to the underlying layers of SiO₂, tungsten, or in one embodiment (shown in FIG. 2) titanium nitride.

In the alternative embodiment of FIG. 2, the titanium nitride layer 9 is placed just below the thin titanium layer 8 to better prevent the formation of an insulating film resulting from reactions between fluorine and the later deposited aluminum layer 10, the presence of fluorine being due to the fact that the tungsten vias are formed using tungsten fluorides.

Next a thin aluminum layer 10 is deposited on the titanium 8 to form the bonding pad. In one embodiment, the aluminum pad 10 is copper doped to approximately 0.5%. Further, the aluminum pad 10 in one embodiment is preferably made relatively thin to approximately 8000 Å to reduce the available aluminum for diffusion at the gold aluminum interface when a gold bonding wire 18 is attached. Diffusion of gold (Au) atoms from the gold bond wire 18 into the aluminum 10 causes Kirkendall voiding in the gold wire, a condition which the thin aluminum layer helps prevent.

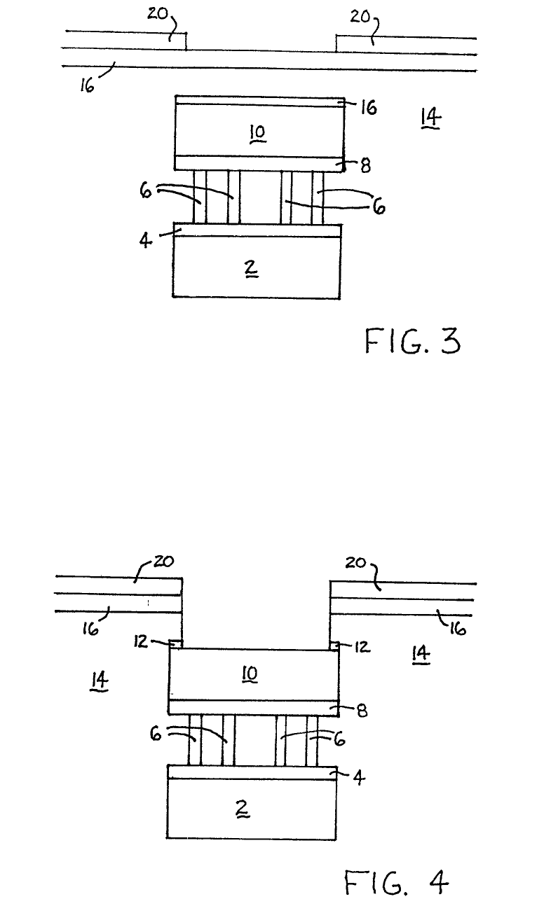

FIG. 3 shows the circuit of FIG. 1 during manufacturing before a passivation etch is applied to layers above the aluminum pad 10. As shown in FIG. 3, before processing, the SiO₂ passivation layer 14 is grown over the entire integrated circuit. A Si₃N₄ layer 16 may then in one embodiment be deposited over the SiO₂ layer as part of the passivation layer. The Si₃N₄ provides a hard crystalline layer to protect the SiO₂.

As further shown in FIG. 2, in one embodiment, a TiN layer is deposited on the aluminum 10 using a titanium arc ion plating process. The titanium 12 prevents formation of a dielectric layer over the aluminum due to fluoride in etching compounds used during subsequent manufacturing steps.

As further shown in FIG. 2, during manufacture, a photoresist mask 20 is formed and patterned as illustrated in FIG. 3 to form an opening over the aluminum pad region 10.

FIG. 4 illustrates the semiconductor device of FIG. 3 following a passivation etch step before removal of the photoresist mask 20. As illustrated, during the passivation etch step, the intent is to remove the portion of the passivation layer, including SiO₂ layer 14, Si₃N₄ layer 16 and TiN layer 12, under the mask opening overlying a portion of the aluminum pad 10. The etch step, in one embodiment, is timed to stop once the passivation layer is calculated to have been removed to expose a region of the aluminum pad 10 underling the mask opening.

In accordance with the present invention, a reactive ion etch (RIE) passivation etch is used which does not include sulfur hexa-fluoride. Instead, the RIE includes argon as the carrier gas, CF₄ and CHF₃ as active etchants and O₂ to reduce the residual halide contaminant in the aluminum pad 10 following the passivation mask.

The process for forming an integrated circuit described in this application is available for very small opening regions above the pad, such as below 60 microns. Further, because components in a typical circuit using a 60 micron or smaller pad opening are small and heat sensitive, thermosonic ball-bonding of a gold wire or ribbon 18 to the aluminum pad 10 is preferably used.

As described previously, thermosonic bonding uses a combination of a relatively low temperature, pressure, and a high frequency to bond the ribbon or wire conductor to the metal interconnect Pad which provides connectivity to the sensitive circuitry. Relatively low temperature indicates a temperature no greater than the temperature that would potentially cause a modification of the circuit parameters of at least one of the system components. Such a minimum temperature may range up to 150 degrees Celsius. The substrate will be heated by the way of a heating plate upon which the integrated substrate is clamped, and pressure is further applied to the substrate. The temperature is applied while the ultrasonic bonding frequency ranging from 60 KHz up to 140 KHz is applied to the clamped structure by means of the wire bonding lead. The combination of the application of high temperature, pressure, and the moderate ultrasonic frequency abrasion is operative to effect metallurgical atomic diffusion bonding of the bond wire with the metal pad bonding site, without causing fracturing or destruction of the gold bonding wire or its interface with the metal bond pad.

Although the present invention has been described above with particularity, this was merely to teach one of ordinary skill in the art how to make and use the invention. Many other modifications will fall within the scope of the invention, as that scope is defined by the claims provided below.

What is claimed is:

1. A method for forming a bonding pad in an integrated circuit, the integrated circuit including an aluminum pad region, and a passivation layer over the aluminum pad region, the method comprising the steps of:
forming a mask over the passivation layer with an opening disposed over the aluminum pad layer;
applying a passive etchant which does not include sulfur to the first passivation layer to remove the passivation layer over the aluminum layer.

2. A method for forming a bonding pad in an integrated circuit, the integrated circuit including an aluminum pad region, and a passivation layer over the aluminum pad region, the method comprising the steps of:
forming a mask over the passivation layer with an opening disposed over the aluminum pad layer;
applying a passive etchant to remove th passivation layer over the aluminum layer, the passive etchant comprising argon as a carrier, CF₄ and CHF₃ as active etchants, and O₂ to reduce residual halide contaminant in the aluminum pad.

3. A method of forming levels of an interconnect structure for an integrated circuit comprising the steps of:
forming a first aluminum interconnect layer;
depositing a first titanium layer on the first aluminum interconnect layer;
covering the first titanium layer with a first insulating layer;
etching openings in the first insulating layer;
depositing tungsten in the openings in the first insulating layer to form vias;
depositing a first titanium layer on the first insulating layer;
depositing a second aluminum layer on the second titanium layer;
depositing a third titanium layer on the second aluminum layer;
forming a passivation layer over the third titanium layer;
forming a mask over the passivation layer with an opening disposed over the aluminum pad layer;
applying a passive etchant to remove the passivation layer over the second aluminum layer, the passive etchant comprising an argon carrier gas, CF₄ and CHF₃ active etchants and O₂ to reduce residual halide contaminant.

4. The method of claim 3, wherein the second titanium layer has a thickness ranging from 150-250 Å.

5. The method of claim 3, wherein the passivation layer comprises:
a layer of SiO, deposited on the third titanium layer; and
a layer of Si₃N₄ deposited on the SiO₂ layer.

6. The method of claim 3, wherein the second aluminum layer has a thickness less than approximately 8000 Å.

7. The method of claim 3, wherein the first and third titanium layers comprise titanium nitride TiN applied with a titanium arc ion plating process.

8. The method of claim 3, wherein the second aluminum layer comprises aluminum doped with copper.

9. The method of claim 8, wherein the copper dopant in the aluminum is approximately 0.5%.

10. The method of claim 3,
wherein the first titanium layer comprises titanium nitride, and
wherein the third titanium layer comprises titanium nitride.

11. The method of claim 3, wherein the first titanium layer comprises:
a layer of titanium nitride covered by a layer of titanium, all deposited over the first layer of aluminum.

12. The method of claim 3, wherein the second titanium layer comprises:
a layer of titanium covered by a layer of titanium nitride, all deposited beneath the second layer of aluminum.

13. The method of claim 3 further comprising the step of bonding a small gold wire to the second aluminum layer.

14. The method of claim 13, wherein the step of bonding a small gold wire comprises the steps of:
heating the interconnect structure to a prescribed temperature; and
bringing a gold wire connector into contact with the second aluminum layer, and ultrasonically vibrating the gold wire to affect a thermosonic bond of the gold wire to the second layer of aluminum.

15. An integrated circuit comprising:
an aluminum interconnect line for connecting to circuitry in the integrated circuit;
an aluminum interconnect pad for bonding to a gold wire interconnect line, the aluminum interconnect pad having a thickness less than approximately 8000 Å;
a first titanium layer overlying the first aluminum interconnect line;
a second titanium layer underlying the second aluminum layer;
at least one tungsten via electrically connecting the first titanium layer to the second titanium layer to form an electrical connection from the first aluminum interconnect line to the second aluminum interconnect pad.

16. An integrated circuit comprising:
an aluminum interconnect line for connecting to circuitry in the integrated circuit;
an aluminum interconnect pad for bonding to a gold wire interconnect line;
a first titanium layer overlying the first aluminum interconnect line;
a second titanium layer underlying the second aluminum layer, the second titanium layer having a thickness ranging from 150-250 Å.
at least one tungsten via electrically connecting the first titanium layer to the second titanium layer to form an electrical connection from the first aluminum interconnect line to the second aluminum interconnect pad.
